(19) United States
(12) Patent Application Publication
(10) Pub. No.: US 2025/0096753 A1
(43) Pub. Date: Mar. 20, 2025

(54) ANTENNA VOLTAGE STANDING WAVE RATIO (VSWR)-TOLERANT TRANSMISSION POWER AMPLIFIER

(71) Applicant: QUALCOMM Incorporated, San Diego, CA (US)

(72) Inventor: Muhammad HASSAN, San Diego, CA (US)

(21) Appl. No.: 18/470,920

(22) Filed: Sep. 20, 2023

(51) Int. Cl. H03F 3/24; H03F 1/02; H03G 3/30; H04B 1/04

(52) U.S. Cl. CPC H03F 3/245; H03F 1/0216; H03G 3/3036; H04B 1/04; H03F 2200/451; H04B 2001/0416

(57) ABSTRACT

Aspects herein describe VSWR-tolerant operation of wireless communication devices. One aspect involves setting, using control circuitry of the wireless communication apparatus, a mission mode for an output transmission (Tx) power amplifier, measuring, using an output power detector, an output power of the output Tx power amplifier operating in the mission mode, measuring, using an input power detector, an input power to the output Tx power amplifier associated with the output power, sampling a thermistor signal to determine a junction temperature associated with the output power, calculating, using the control circuitry, a gain value for the output Tx power amplifier using the input power and the output power, comparing, using the control circuitry; the gain value with a temperature calibrated reference gain value selected using the junction temperature, and adjusting a power amplifier bias when the gain value is different from the temperature calibrated reference gain value.

### FIELD

The present disclosure relates generally to electronics and wireless communications. For example, aspects of the present disclosure relate to transmission (Tx) power amplifiers for wireless signals, which are configured to tolerate antenna voltage standing wave ratio (VSWR) variations.

### BACKGROUND

Wireless communication devices and technologies are becoming ever more prevalent, as are communication devices that operate at millimeter-wave (mmW) frequencies. Wireless communication devices generally transmit and/or receive communication signals.

A communication signal is typically processed by a variety of different components and circuits. In some modern communication systems, a communication beam may be formed and steered in one or more directions. One type of beam steering system uses what is referred to as phased array, or phased array antenna system. A phased array may use a number of different elements and antennas where each element may process a transmit and/or receive signal that is offset in phase by some amount, leading to different elements of a phased array system processing slightly phase-shifted versions of a transmit and/or a receive signal. A phased array system may produce narrow, steerable, high power communication beams. A phased array antenna system may also form part of a massive multiple-input, multiple-output (MIMO) system. A transmitter in a phased array communication system may have a number of transmit paths and may have a number of amplifiers, including a number of power amplifiers. A variety of factors influence the operation of a power amplifier, including, for example, input signal strength, input impedance, output impedance, load impedance, and other factors. These factors may influence the longevity and reliability of a power amplifier.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

In some aspects, a method is provided. The method comprises setting, using control circuitry of the wireless communication apparatus, a mission mode for an output transmission (Tx) power amplifier, measuring, using an output power detector, an output power of the output Tx power amplifier operating in the mission mode, measuring, using an input power detector, an input power to the output Tx power amplifier associated with the output power, sampling a thermistor signal to determine a junction temperature associated with the output power, calculating, using the control circuitry, a gain value for the output Tx power amplifier using the input power and the output power, comparing, using the control circuitry, the gain value with a temperature calibrated reference gain value selected using the junction temperature, and adjusting a power amplifier bias when the gain value is different from the temperature calibrated reference gain value. Some such aspects operate where adjusting the power amplifier bias comprises: incrementing a counter that used to generate the power amplifier bias when the gain value is above the temperature calibrated reference gain value, and decrementing the counter when the gain value is below the temperature calibrated reference gain value. Some such aspects further include updating the gain value with an updated output power measurement, an updated input power measurement, and an updated thermistor sample approximately every millisecond (ms), and updating the power amplifier bias as part of a voltage standing wave ratio (VSWR) compensation loop.

Some such aspects further include estimating a voltage standing wave ratio (VSWR) value using the input power and the output power, and signaling a power back-off of the output Tx power amplifier based on the VSWR value exceeding a threshold value, without using a peak detector measurement for the signaling of the power back-off.

Some such aspects further include estimating a voltage standing wave ratio (VSWR) value using the input power and the output power, and performing, using the control circuitry, an output Tx power amplifier protection action based on the VSWR value. Some such aspects operate where the output Tx power amplifier protection action comprises adjusting a gate bias value for the output Tx power amplifier when the VSWR value is less than 2:1.

Some such aspects operate where the output Tx power amplifier protection action comprises adjusting an input power to the output Tx power amplifier when the VSWR value is greater than 2:1.

Some such aspects operate where the output Tx power amplifier protection action comprises adjusting an automatic gain control setting of the output Tx power amplifier when the VSWR value is greater than 2:1.

Some such aspects further include comparing, using the control circuitry, the gain value with a low impedance estimate threshold value, and lowering a supply voltage for the output Tx power amplifier and increasing the power amplifier bias to improve a linear power efficiency when the gain value is below the low impedance estimate threshold value.

Some such aspects further include comparing, using the control circuitry, the gain value with a high impedance estimate threshold value, and setting a supply voltage for the output Tx power amplifier to a maximum value and lowering an input power to the output Tx power amplifier.

Another aspect is an additional method. The method includes setting, using control circuitry of the wireless communication apparatus, a mission mode for a Cascode sliced output transmission (Tx) power amplifier, measuring, using an output power detector, an output power of the Cascode sliced output Tx power amplifier operating in the mission mode, measuring, using an input power detector, an input power to the Cascode sliced output Tx power amplifier associated with the output power, sampling a thermistor signal to determine a junction temperature associated with the output power, calculating, using the control circuitry, a gain value for the Cascode sliced output Tx power amplifier using the input power and the output power, comparing, using the control circuitry, the gain value with a temperature calibrated reference gain value selected using the junction temperature, and adjusting a gain bit setting for the Cascode sliced output Tx power amplifier when the gain value has more than a threshold difference from the temperature calibrated reference gain value.

Some such aspects further include estimating a voltage standing wave ratio (VSWR) value using the input power and the output power, and performing, using the control circuitry, an output Tx power amplifier protection action based on the VSWR value. Some such aspects operate where the output Tx power amplifier protection action comprises adjusting a gate bias value for the output Tx power amplifier when the VSWR value is less than a threshold value. Some such aspects operate where the output Tx power amplifier protection action comprises adjusting the gain bit setting to lower the gain value when the VSWR value is greater than a threshold value. Some such aspects operate where the output Tx power amplifier protection action comprises signaling a power back-off of the output Tx power amplifier based on the VSWR value exceeding a threshold value, without using a peak detector measurement for the signaling of the power back-off.

A method, comprising: setting, using control circuitry of a wireless communication apparatus, a mission mode for a multi-element output transmission (Tx) power path comprising a plurality of transmit elements, calculating individual gain values for the plurality of transmit elements, calculating a mean operating gain from the individual gain values, comparing the mean operating gain with the individual gain values; and adjusting a bias setting for one or more of the plurality of transmit elements when a first gain value of the individual gain values is not within a threshold distance of the mean operating gain.

Some such aspects further involve estimating corresponding voltage standing wave ratio (VSWR) values for transmit elements the multi-element output Tx power path, determining a highest VSWR value of the corresponding VSWR values, performing, using control circuitry, an output Tx power amplifier protection action based on the highest VSWR value of the corresponding VSWR values. Some such aspects further involve deterring a lowest VSWR value of the corresponding VSWR values, where the output Tx power amplifier protection action comprises adjusting a gate bias value for a power amplifier of the plurality of transmit elements when the lowest VSWR value is less than a threshold value. Some such aspects operate where the output Tx power amplifier protection action comprises adjusting an input power to the multi-element output Tx power path when the highest VSWR value is greater than a threshold value. Some such aspects operate where the output Tx power amplifier protection action comprises adjusting an antenna tuning circuit coupled to the output of the multi-element output Tx power path when a difference between the mean operating gain and a target reference gain value is greater than a predefined threshold value.

Another aspect is an additional method. The method involves setting, using control circuitry of a wireless communication apparatus, a mission mode for an output transmission (Tx) power amplifier, measuring, using an output power detector, an output power of the output Tx power amplifier operating in the mission mode, measuring, using an input power detector, an input power to the output Tx power amplifier associated with the output power, sampling a thermistor signal to determine a junction temperature associated with the output power, calculating, using the control circuitry, a gain value for the output Tx power amplifier using the input power and the output power, comparing, using the control circuitry, the gain value with a temperature calibrated reference gain value selected using the junction temperature, and adjusting an antenna tuning circuit when the gain value does not match the temperature calibrated reference gain value.

In some aspects, the apparatuses described above can include a mobile device with a camera for capturing one or more pictures. In some aspects, the apparatuses described above can include a display screen for displaying one or more pictures. In some aspects, additional wireless communication circuitry. The summary is not intended to identify key or essential features of the claimed subject matter, nor is it intended to be used in isolation to determine the scope of the claimed subject matter. The subject matter should be understood by reference to appropriate portions of the entire specification, any or all drawings, and each claim.

The foregoing, together with other features and embodiments, will become more apparent upon referring to the following specification, claims, and accompanying drawings.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless communication system communicating with a wireless device that can be implemented according to aspects described herein.

FIG. 2A is a block diagram showing portions of a wireless device in which aspects of the present disclosure may be implemented.

FIG. 2B is a block diagram showing portions of a wireless device in which aspects of the present disclosure may be implemented.

FIG. 2C is a block diagram illustrating aspects of a wireless device in which aspects of the present disclosure may be implemented.

FIG. 3 is a block diagram of a system that can be used with a VSWR-tolerant operating for an array of antenna elements in accordance with aspects described herein.

FIG. 4 is a diagram illustrating aspects of a power amplifier configured for VSWR-tolerant operation in accordance with aspects described herein.

FIG. 5 is a flow diagram describing a method for operation of a device configured for antenna VSWR-tolerant operation in accordance with some aspects.

FIG. 6 is a functional block diagram of an apparatus including a power amplifier configured for antenna VSWR-tolerant operation in accordance with some aspects.

FIG. 7 is a diagram illustrating aspects of a power amplifier configured for VSWR-tolerant operation in accordance with aspects described herein.

FIG. 8 is a flow diagram describing a method for operation of a device configured for antenna VSWR-tolerant operation in accordance with some aspects.

FIG. 9 is a functional block diagram of an apparatus including a power amplifier configured for antenna VSWR-tolerant operation in accordance with some aspects.

FIG. 10A is a diagram illustrating aspects of a power amplifier configured for VSWR-tolerant operation in accordance with aspects described herein.

FIG. 10B is a diagram illustrating aspects of an antenna tuning circuit for use with a power amplifier configured for VSWR-tolerant operation in accordance with aspects described herein.

FIG. 11 is a flow diagram describing a method for operation of a device configured for antenna VSWR-tolerant operation in accordance with some aspects.

FIG. 12 is a functional block diagram of an apparatus including a power amplifier configured for antenna VSWR-tolerant operation in accordance with some aspects.

### DETAILED DESCRIPTION

The detailed description set forth below in connection with the appended drawings is intended as a description of exemplary implementations and is not intended to represent the only implementations in which the invention may be practiced. The detailed description includes specific details for the purpose of providing a thorough understanding of the exemplary implementations.

The progression of wireless communication infrastructure, such as for Third Generation Partnership Project (3GPP) fifth generation (5G) systems, involves increasing importance of the radio frequency (RF) front end (RFFE) module. Such RFFE modules can include transmission (Tx) power amplifiers that provide a full strength output signal to a transmit antenna. In a communication system that uses a phased array antenna system having phased array elements, each phased array element can include an associated power amplifier. Each power amplifier may have a corresponding input power detector and output power detector. An input power detector may be referred to as an RDET (reliability input power detector), and an output power detector may be referred to as a PDET (power detector, or output power detector).

An RDET may be part of an input protection circuit to prevent over-driving the power amplifier, which can degrade performance and long term reliability. An RDET detects the voltage swing, or voltage level, at the input of the power amplifier, and the PDET can similarly detect output power swings. Information about individual power amplifier input and output swings can be used to improve device performance.

The antenna impedance of antennas coupled to power amplifier paths can vary due to antenna blocking or holding, the housing or packaging for the power amplifier circuitry, active pulling of the power amplifier in a phased array system, impacts of objects touching or coming near an antenna, or other variables. Such variations in antenna impedance can introduce a large power amplifier gain variation across antenna voltage standing wave ratios (VSWRs) that are associated with different antenna impedances. Aspects described herein can use RDET and PDET measurements along with control circuitry logic to manage gain and linearity impacts associated with antenna VSWR.

Further details regarding aspects described herein are provided with respect to the figures below.

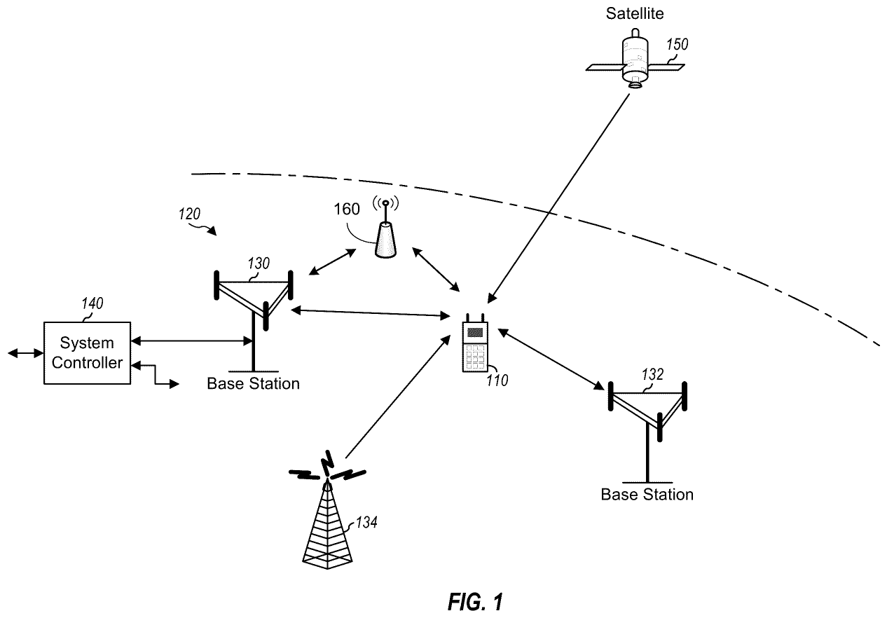

FIG. 1 is a diagram showing a wireless device 110 communicating with a wireless communication system 120. In accordance with aspects described herein, the wireless device can include a transceiver with an RFFE including one or more power amplifiers configured for antenna VSWR-tolerant operation in accordance with aspects described herein. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. Communication elements of the wireless device 110 for implementing mmW and non-mmW communications in accordance with any such communication standards can be supported by various designs in accordance with aspects described herein. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, or other such mobile device (e.g., a device integrated with a display screen). Other examples of the wireless device 110 include a wireless modem, a personal digital assistant (PDA), a handheld device, a laptop computer, a smartbook, a netbook, a tablet, a cordless phone, a medical device, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or signals from satellites (e.g., a satellite 150 in one or more global navigation satellite systems (GNSS), etc.). Wireless device 110 may support one or more radio technologies for wireless communication such as LTE, WCDMA, CDMA 1X, EVDO, TD-SCDMA, GSM, 802.11, 5G, etc.

The wireless communication system 120 may also include a wireless device 160. In an exemplary embodiment, the wireless device 160 may be a wireless access point, or another wireless communication device that comprises, or comprises part of a wireless local area network (WLAN). In an exemplary embodiment, the wireless device 110 may be configured as a customer premises equipment (CPE), which may be in communication with a base station 130 and another wireless device 110, or other devices in the wireless communication system 120. In some embodiments, the CPE may be configured to communicate with the wireless device 160 using WAN signaling and to interface with the base station 130 based on such communication instead of the wireless device 160 directly communicating with the base station 130. In exemplary embodiments where the wireless device 160 is configured to communicate using WLAN signaling, a WLAN signal may include WiFi, or other communication signals.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types—intra-band CA and inter-band CA. Intra-band CA refers to operation on multiple carriers within the same band. Inter-band CA refers to operation on multiple carriers in different bands.

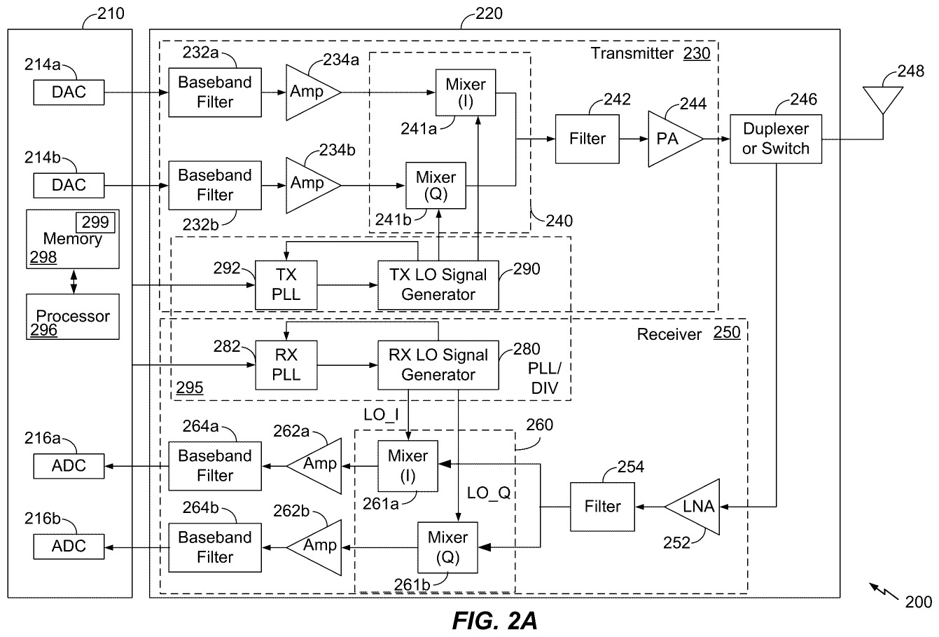

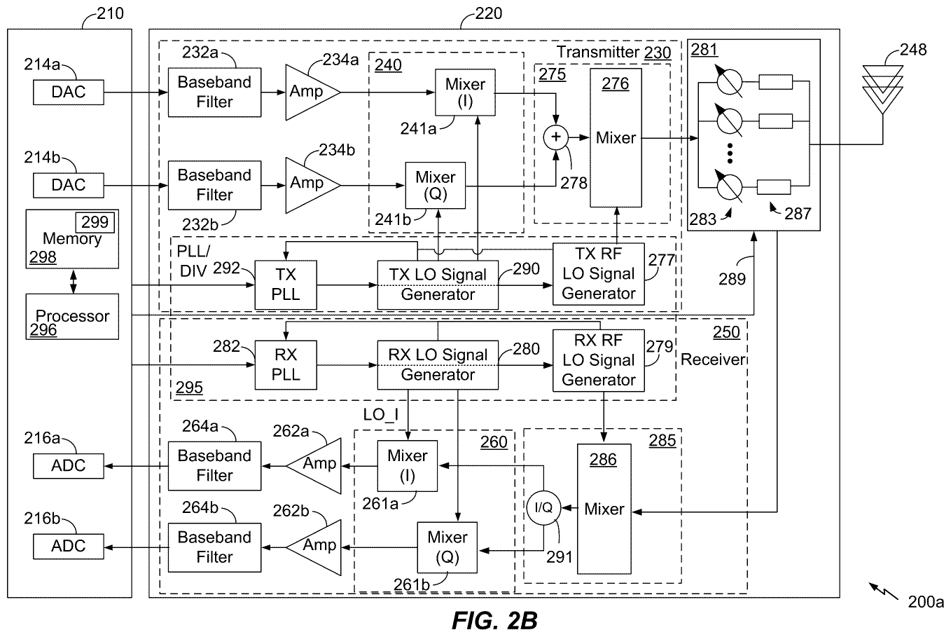

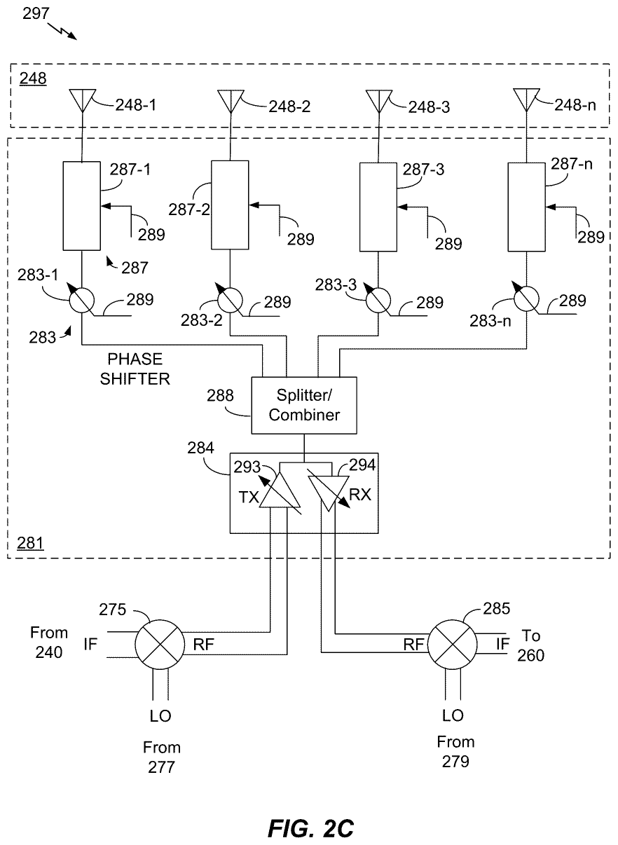

FIG. 2A is a block diagram showing a wireless device 200 in which aspects of the present disclosure may be implemented. The wireless device 200 may, for example, be an embodiment of the wireless device 110 illustrated in FIG. 1. Circuitry described may be circuitry supporting mmW communications or transmissions, as well as radio frequency non-mmW signaling. In some examples, the wireless device 200 (or any of the devices described and/or illustrated hereinafter) may be an example of any of the devices illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier 244 amplifies the signal from filter 242 to obtain the desired output power level and provides a transmit RF signal. The transmit RF signal is routed through a duplexer or switch 246 and transmitted via an antenna array 248. While examples discussed herein utilize I and Q signals, those of skill in the art will understand that components of the transceiver may be configured to utilize polar modulation.

In the receive path, the antenna array 248 receives communication signals and provides a received RF signal, which is routed through duplexer or switch 246 and provided to a low noise amplifier (LNA) 252. The switch 246 is designed to operate with a specific RX-to-TX duplexer frequency separation, such that RX signals are isolated from TX signals. The received RF signal is amplified by LNA 252 and filtered by a filter 254 to obtain a desired RF input signal. Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

In an exemplary embodiment, the RX PLL 282, the TX PLL 292, the RX LO signal generator 280, and the TX LO signal generator 290 may alternatively be combined into a single LO generator circuit 295, which may include common or shared LO signal generator circuitry to provide the TX LO signals and the RX LO signals. Alternatively, separate LO generator circuits may be used to generate the TX LO signals and the RX LO signals.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the switch 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, power amplifier 244 and LNA 252 (and filter 242 and/or 254 in some examples) may be implemented separately from other components in the transmitter 230 and receiver 250, and may be implemented on a millimeter wave integrated circuit. An example super-heterodyne architecture is illustrated in FIG. 2B.

FIG. 2B is a block diagram showing a wireless device in which aspects of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). For example, the upconverter 240 may be configured to provide an IF signal to an upconverter 275. In an exemplary embodiment, the upconverter 275 may comprise summing function 278 and upconversion mixer 276. The summing function 278 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 289 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287.

Each phase shifter 283 may be configured to receive the transmit signal from the upconverter 275, alter the phase by an amount, and provide the signal to a respective phased array element 287. Each phased array element 287 may comprise transmit and/or receive circuitry including one or more filters, amplifiers, driver amplifiers, and power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise an I/Q generation function 291 and a downconversion mixer 286. In an exemplary embodiment, the mixer 286 downconverts the receive signal provided by the phase shift circuitry 281 to an IF signal according to RX LO signals provided by an RX LO signal generator 279. The I/Q generation function 291 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect. For example, components of the antenna array 248 may be implemented on a substrate and coupled to an integrated circuit implementing the phase shift circuitry 281 via a flexible printed circuit board or other such substrate.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from transmission frequencies and signals that have been downconverted from transmission frequencies to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B.

FIG. 2C is a block diagram 297 showing in greater detail an embodiment of some of the components of FIG. 2B. In an exemplary embodiment, the upconverter 275 provides a transmit signal to the phase shift circuitry 281 and the downconverter 285 receives a receive signal from the phase shift circuitry 281. In an exemplary embodiment, the phase shift circuitry 281 comprises a variable gain amplifier 284, a splitter/combiner 288, the phase shifters 283 and the phased array elements 287. In an exemplary embodiment, the phase shift circuitry 281 may be implemented on a millimeter-wave integrated circuit (mmWIC). In some such embodiments, the upconverter 275 and/or the downconverter 285 (or just the mixers 276, 286) are also implemented on the mmWIC. In an exemplary embodiment, the mmW VGA 284 may comprise a TX VGA 293 and an RX VGA 294. In some embodiments, the TX VGA 293 and the RX VGA 294 may be implemented independently. In other embodiments, the VGA 284 is bidirectional. In an exemplary embodiment, the splitter/combiner 288 may be an example of a power distribution network and a power combining network. In some embodiments, the splitter/combiner 288 may be implemented as a single component or as a separate signal splitter and signal combiner. The phase shifters 283 are coupled to respective phased array elements 287. Each respective phased array element 287 is coupled to a respective antenna element in the antenna array 248. In an exemplary embodiment, phase shifters 283 and the phased array elements 287 receive control signals from the data processor 210 over connection 289. The exemplary embodiment shown in FIG. 2C comprises a 1×4 array having four phase shifters 283-1, 283-2, 283-3 and 283-n, four phased array elements 287-1, 287-2, 287-3 and 287-n, and four antennas 248-1, 248-2, 248-3 and 248-n. However, a 1×4 phased array is shown for example only, and other configurations, such as 1×2, 1×6, 1×8, 2×3, 2×4, or other configurations are possible.

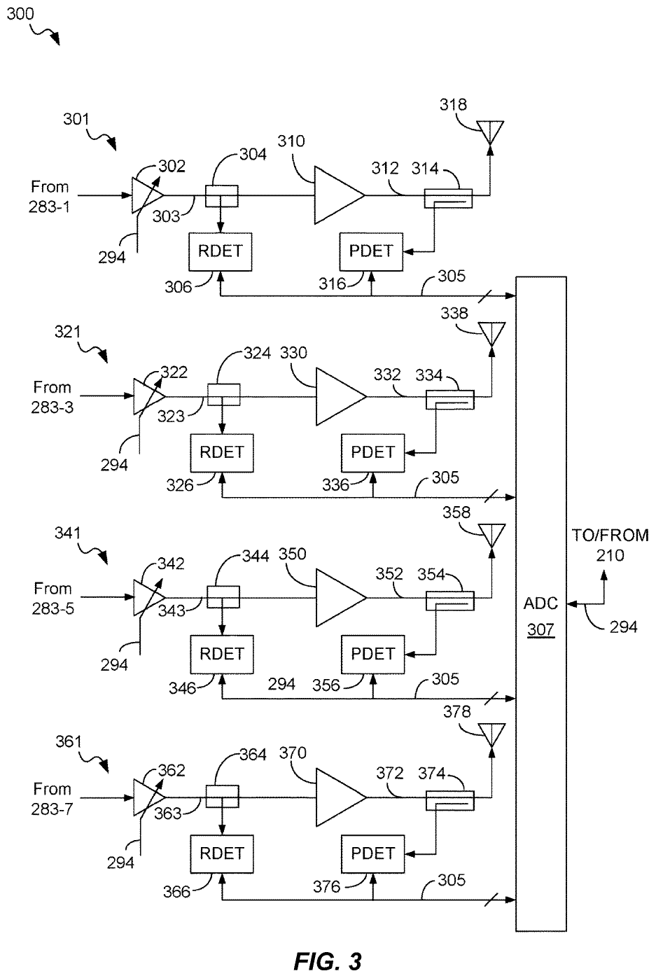

FIG. 3 is a block diagram of a portion of a phased array circuit 300 in accordance with some aspects of the disclosure. In some aspects, the phased array circuit 300 is an example of a phased array transmit system having four (4) transmit paths 301, 321, 341 and 361. The phased array circuit 300 may also be referred to as a phased array. Four transmit paths are shown for example only, as more or fewer transmit paths may be implemented in a phased array system. In some aspects, the transmit paths 301, 321, 341 and 361 may be configured to receive respective outputs of the phase shifters 283-1, 283-3, 283-5 and 283-7 of FIG. 2C, or configured to receive signals that have varied phases produced using other means.

In some aspects, the transmit path 301 may comprise one or more driver amplifiers, shown as a single driver amplifier 302 in this example, a power amplifier 310 and an antenna 318. In some aspects, the transmit path 301 may include multiple gain stages, with the power amplifier 310 operating as the final output Tx power amplifier that provides the full transmit power to the antenna 318. In some aspects, the power amplifier 310 can be implemented as a Cascode controlled power amplifier, with multiple amplifiers that are code controlled to adjust gain values for the power amplifier 310, as detailed further below. The transmit path 301 may also comprise an input power detector (referred to as a reliability input power detector RDET) 306 and an output power detector, PDET 316. The output power detector, PDET 316, may be coupled to the connection 312 between the power amplifier 310 and the antenna 318 using a (power) coupler 314. The input power detector, RDET 306, may be coupled to the connection 303 between the driver amplifier 302 and the power amplifier 310 using a (power) coupler 304. In some aspects, the power amplifier 310 may be an example of one of the amplifiers in FIG. 2C. In some aspects, the input power detectors, RDETs 306, 326, 346 and 366, may be configured to measure an input voltage swing at the input to respective power amplifiers 310, 330, 350 and 370. As used herein, the term “input power” may also be referred to as “input voltage swing” or “voltage swing.”

In some aspects, the transmit path 321 may comprise one or more driver amplifiers, shown as a single driver amplifier 322 in this example, a power amplifier 330 and an antenna 338. The transmit path 321 may also comprise an input power detector, RDET 326 and an output power detector, PDET 336. The output power detector, PDET 336, may be coupled to the connection 332 between the power amplifier 330 and the antenna 338 using a (power) coupler 334. The input power detector, RDET 326, may be coupled to the connection 323 between the driver amplifier 322 and the power amplifier 330 using a (power) coupler 324. In some aspects, the power amplifier 330 may be an example of one of the amplifiers in FIG. 2C.

In some aspects, the transmit path 341 may comprise one or more driver amplifiers, shown as a single driver amplifier 342 in this example, a power amplifier 350 and an antenna 358. The transmit path 341 may also comprise an input power detector, RDET 346 and an output power detector, PDET 356. The output power detector, PDET 356, may be coupled to the connection 352 between the power amplifier 350 and the antenna 358 using a (power) coupler 354. The input power detector, RDET 346, may be coupled to the connection 343 between the driver amplifier 342 and the power amplifier 350 using a (power) coupler 344. In some aspects, the power amplifier 350 may be an example of one of the amplifiers in FIG. 2C.

In some aspects, the transmit path 361 may comprise one or more driver amplifiers, shown as a single driver amplifier 362 in this example, a power amplifier 370 and an antenna 378. The transmit path 361 may also comprise an input power detector, RDET 366 and an output power detector, PDET 376. The output power detector, PDET 376, may be coupled to the connection 372 between the power amplifier 370 and the antenna 378 using a (power) coupler 374. The input power detector, RDET 366, may be coupled to the connection 363 between the driver amplifier 362 and the power amplifier 370 using a (power) coupler 364.

In some aspects, each driver amplifier 302, 322, 342 and 362 may be coupled over a connection to the data processor 210 (FIG. 2B), from which respective control signals may be applied to the driver amplifiers 302, 322, 342 and 362. In some aspects, each RDET 306, 326, 346 and 366 and each PDET 316, 336, 356 and 376 may be coupled over a connection 305 to an analog-to-digital converter (ADC) 307. The ADC 307 may be coupled over a connection to the data processor 210 (FIG. 2B). In some aspects, the ADC 307 may be located on the same circuit, chip or die as the driver amplifiers, power amplifiers, input power detectors and/or output power detectors. Alternatively, the ADC 307 may be located on circuitry other than the circuitry on which the driver amplifiers, power amplifiers, input power detectors and/or output power detectors are located. Further, separate ADCs may be implemented for one or more of the transmit paths and/or for one or more of the RDET(s) and PDET(s) instead of having one ADC coupled to all of the RDETs and

In some aspects, the ADC 307 may receive power measurements from the input power detectors, RDETs 306, 326, 346 and 366, and may receive power measurements from the output power detectors, PDETs 316, 336, 356 and 376 over connection 305. In some aspects, the connection 305 may comprise a communication bus configured to transport multiple signals simultaneously. In some aspects, the measurements from the input power detectors and output power detectors may be provided to the ADC 307. In some aspects, the ADC 307 may develop one or more signals representative of the power detected by the input power detectors, RDETs, 306, 326, 346 and 366, and may develop one or more signals representative of the power detected by the output power detectors, PDETs, 316, 336, 356 and 376. The ADC 307 may be in communication with the data processor 210 (FIG. 2B) and the data processor 210 may be configured to perform calculations on the power measurement signals developed by the ADC 307. Similarly, the data processor 210 may control the operation of each of the driver amplifiers and indirectly, the power amplifiers, in some embodiments, responsive to the power detected by the input power detectors and the output power detectors. In other examples, the data processor 210 may directly control operation of one or more of the power amplifiers.

In some aspects, the data processor 210 may develop control signals for the driver amplifiers 302, 322, 342 and 362 to provide power control. In some aspects, there are two controls: one control is a coarse control referred to as automatic gain control, (AGC), and the other control is a fine control. The fine control may be used to perform power amplifier power output mismatch calibration as described herein and in some aspects, can be done in the driver amplifiers 302, 322, 342 and 362 to indirectly control the power provided by the power amplifiers 310, 330, 350 and 370. The coarse power control (AGC) may be done in a VGA, such as in the RF VGA 284 of FIG. 2C because in this example the RF VGA 284 is common to all transmit paths 301, 321, 341 and 361. The coarse control (AGC) may also be used for power backoff as will be described below.

In some aspects, each antenna 318, 338, 358 and 378 may be associated with a communication port. For example, antenna 318 may be associated with a first communication port (port 1), antenna 338 may be associated with a second communication port (port 2), antenna 358 may be associated with a third communication port (port 3), and antenna 378 may be associated with a fourth communication port (port 4).

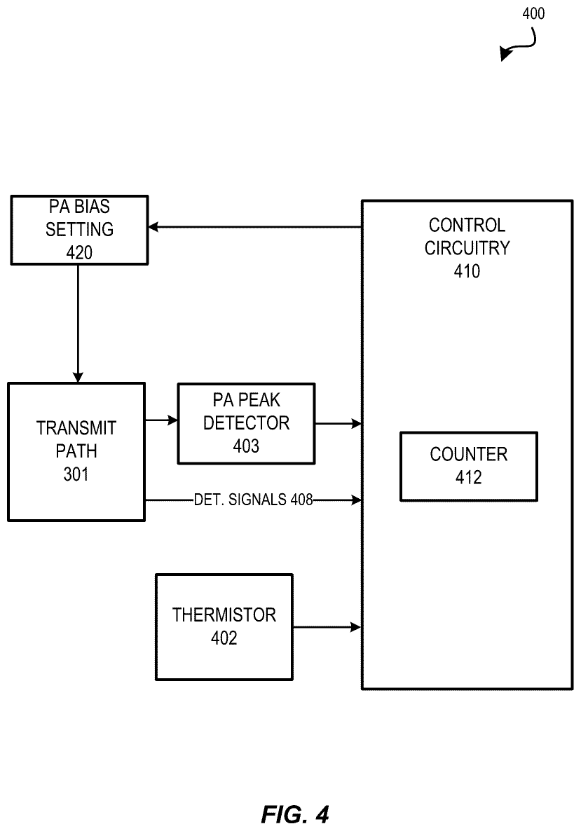

FIG. 4 is a diagram illustrating aspects of a power amplifier (e.g., similar to the power amplifier 310) in a transmit path 401 configured for VSWR-tolerant operation in accordance with aspects described herein. FIG. 4 illustrates aspects of a device 400 that includes a transmit path 401 (e.g., similar to the transmit path 301 of FIG. 3, with additional circuitry configured for VSWR-tolerant operation). The device 400 includes control circuitry 410, as well as counter 412 circuitry. The device further includes a thermistor 402, which can be used to determine temperatures within the device (e.g., at a final stage output Tx power amplifier of the transmit path 401) during device operation, and a power amplifier peak detector 403.

The control circuitry 410 can, in some aspects, be a digital control integrated circuit configured to perform a control loop of repeated operations to manage RFFE performance, transmitter performance, or any performance associated with elements of a wireless communication apparatus. The control circuitry (e.g., an ADC such as the ADC 307) can receive thermistor 402 output signals. Such signals can, in some aspects, be continuous analog signals that are sampled by the control circuitry 410 and processed to estimate (e.g., calculate) a temperature value for the device 400. The control circuitry 410 can additionally receive detection signals 408 from the transmit path 401, and can provide power amplifier bias settings 420 to the transmit path 401, along with other operations and signaling. The detection signals 408 can be signals from RDET 306, PDET 316, and any other signal from the transmit path 401. Similar signaling can also be received from each other signal path in a device (e.g., the signal paths 321, 341, 361, etc.).

As indicated above, a variety of operating environments can impact the VSWR of a transmit path. The final stage (e.g., including an output Tx power amplifier) of a transmit path can particularly be subject to damage or excessive operating wear if the operating VSWR conditions push the output Tx power amplifier outside of preferred operating conditions. Such operating conditions can include changes or structural impacts on VSWR associated with an antenna and transmit path housing (e.g., a package). Such operating conditions can also include proximity of an antenna to an external object (e.g., a finger touching an antenna). Such operating conditions can further include active pulling on a particular output Tx power amplifier in a phased array system.

Existing designs use circuitry such as a power amplifier peak detector 403 to identify certain types of extreme operating conditions, but such a peak detector 403 only identifies a subset of performance issues for certain extreme operating conditions, and cannot track VSWR changes from operating conditions that can impact device performance (e.g., linearity, efficiency, stability, etc.) and not be flagged by a peak detector 403 identifying a peak threshold being exceeded. Additionally, certain low impedance VSWR conditions result in standard peak detection operations or processes using the power amplifier peak detector 403 failing to accurately identify the problematic very low impedance VSWR condition.

As part of VSWR-tolerant operation, control circuitry 410 can include a memory, table, algorithm, or other such systems to access temperature calibrated reference gain values. Such values can, in some aspects, be generated and stored on an individual device basis during manufacturing and testing of a device, with sample values selected for associated temperature ranges and stored in a table of the control circuitry 410. Such values can, in some aspects, be modeled, with device specific variables provided to control circuitry 410 during device testing. Such values can also be estimated during design, with temperature calibrated reference gain values estimated for a design or a group of devices based on batch characteristics.

Aspects described herein can use samples from the thermistor 402 to identify a real or near real-time operating condition (e.g., delayed by the loop frequency or other operations performed by the control circuitry 410) of a specific device (e.g., the device 400), and then identify the corresponding temperature calibrated reference gain value associated with the temperature operating condition determined from the thermistor 402 signal samples.

An actual real or near real-time gain of an output Tx power amplifier (e.g., the output Tx power amplifier 310 can similarly be taken from RDET 306 and PDET 316 measurements which are taken at or near a time when the thermistor 402 signal samples are taken. The control circuitry 410 can then compare the temperature calibrated reference gain value associated with the temperature operating condition determined from the thermistor 402 signal samples, to the actual gain value determined from RDET 306 and PDET 316 measurements. The difference between the calibrated gain value and the measured gain value corresponds to VSWR changes that can be caused by operating conditions, as detailed above. The control circuitry 410 can use the difference between the calibrated gain value and the measured gain value, to adjust the power amplifier bias settings 420.

In some aspects, the power amplifier bias settings 420 can be used to control a bias input in an output Tx power amplifier of the signal path 401. In other aspects, replica diodes or other bias circuitry can be used to adjust the output Tx power amplifier of the signal path. Similarly, such settings can be adjusted as described above on an independent basis as part of a logic loop processing information for each signal path of a device.

In some aspects, the control circuitry 410 performs a loop, and at each instance of the loop, increments or decrements a counter 412, depending on whether the measured gain value is above or below the accessed calibrated gain value. If the measured value is above the calibrated value, the control circuitry 410 decrements (or takes an action to lower a bias value) the counter 412. If the measured value is below the calibrated value, the control circuitry increments (e.g., takes an action to increase a bias value) the counter 412.

In some aspects, the difference between the accessed calibrated gain value and the measured gain is used to respond to the VSWR. In some aspects, the PA bias setting 420 is adjusted in response to this difference (e.g., adjusting a voltage value, such as a VDD voltage supply to the output Tx power amplifier). In other aspects, gain slicing inside the output Tx power amplifier is used as an adjustment in response to the difference between the accessed calibrated gain value and the measured gain.

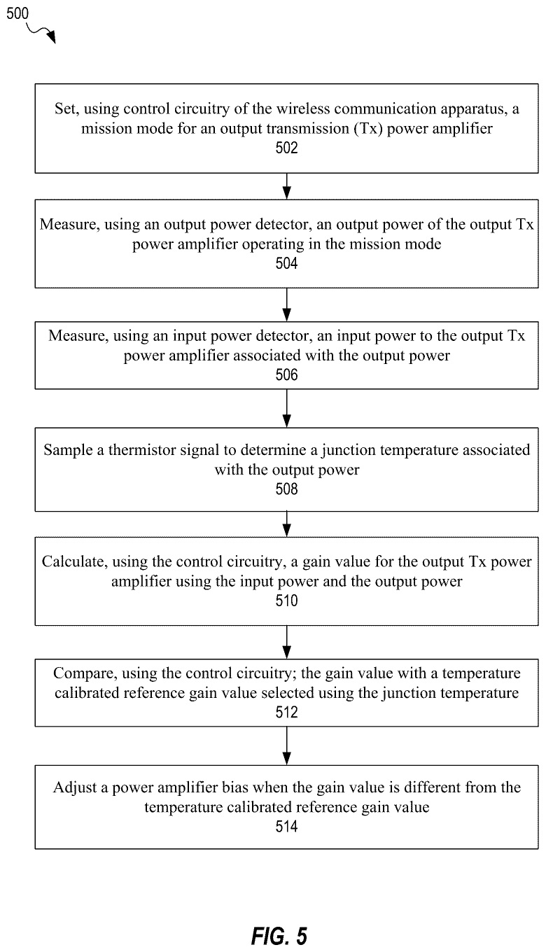

FIG. 5 is a flow diagram describing a method for operation of a device in accordance with aspects described herein. The blocks in the method 500 can be performed in or out of the order shown, and in some embodiments, can be performed at least in part in parallel.

Method 500 includes block 502, which involves setting, using control circuitry of the wireless communication apparatus, a mission mode for an output transmission (Tx) power amplifier. The method 500 further includes block 504, which involves measuring, using an output power detector, an output power of the output Tx power amplifier operating in the mission mode. The method 500 further includes block 506, which involves measuring, using an input power detector, an input power to the output Tx power amplifier associated with the output power. The method 500 further includes block 508, which involves sampling a thermistor signal to determine a junction temperature associated with the output power. The method 500 further includes block 510, which involves calculating, using the control circuitry, a gain value for the output Tx power amplifier using the input power and the output power. The method 500 further includes block 512, which involves comparing, using the control circuitry; the gain value with a temperature calibrated reference gain value selected using the junction temperature. The method 500 further includes block 514, which involves adjusting a power amplifier bias when the gain value is different from the temperature calibrated reference gain value.

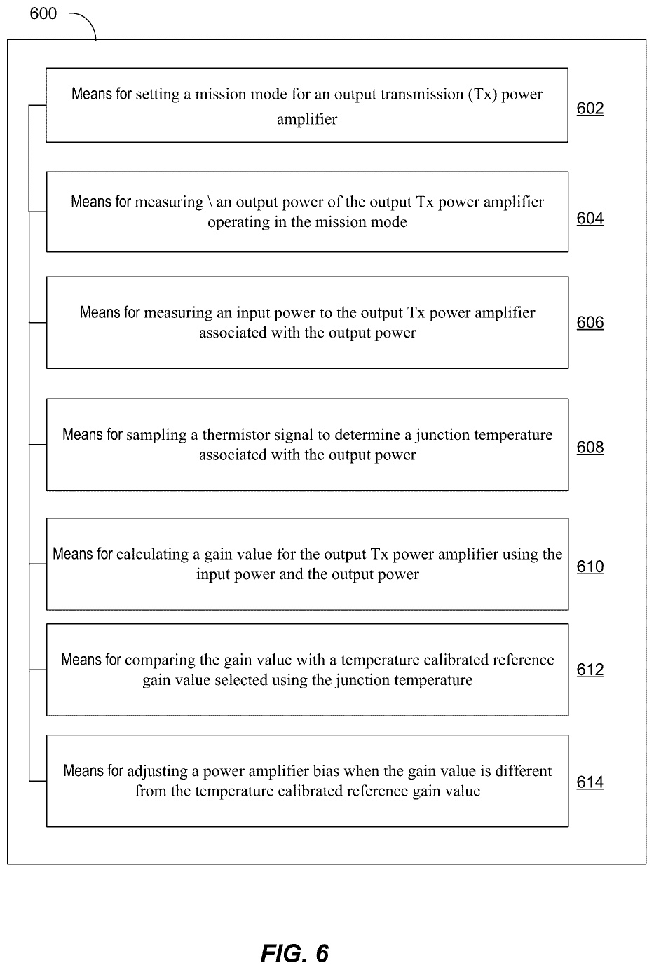

FIG. 6 is a functional block diagram of an apparatus including a power amplifier configured for VSWR-tolerant operation in accordance with some aspects. The apparatus 600 comprises means 602 for setting a mission mode for an output transmission (Tx) power amplifier, means 604 for measuring an output power of the output Tx power amplifier operating in the mission mode, means 606 for measuring an input power to the output Tx power amplifier associated with the output power, means 608 for sampling a thermistor signal to determine a junction temperature associated with the output power, means 610 for calculating a gain value for the output Tx power amplifier using the input power and the output power, means 612 for comparing the gain value with a temperature calibrated reference gain value selected using the junction temperature, and means 614 for adjusting a power amplifier bias when the gain value is different from the temperature calibrated reference gain value.

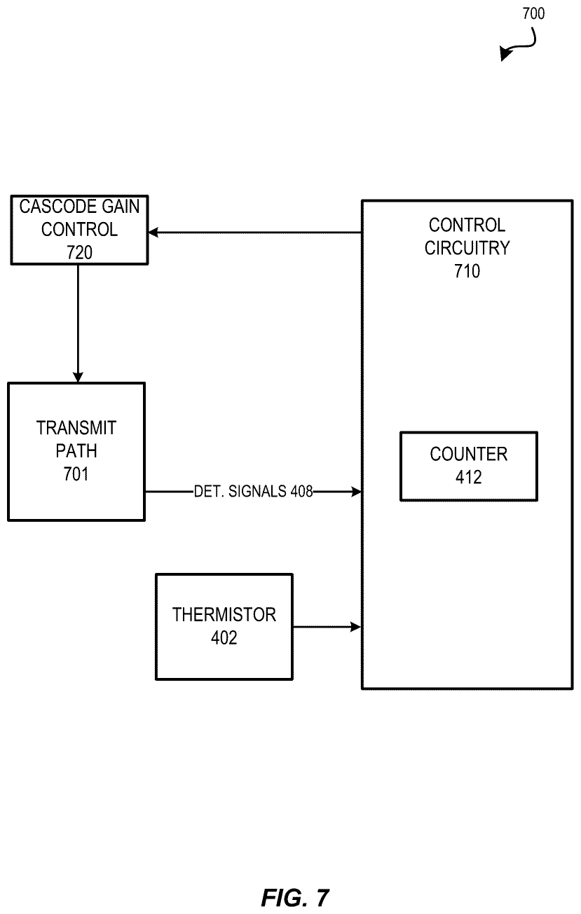

FIG. 7 is a diagram illustrating aspects of a device 700 including a power amplifier implemented as gain slicing blocks configured for VSWR-tolerant operation in accordance with aspects described herein. As described above, in some aspects, an output Tx power amplifier of a transmission signal path can include a bias, replica diode, or other configurable element that can be tuned using a gain measurement compared with a temperature calibrated gain value associated with a temperature estimated from a thermistor measurement taken at the same time as the gain measurements (e.g., RDET and PDET measurements of detection signals 408). The device 700 of FIG. 7, includes a transmit path 701 where the output Tx power amplifier of the transmit path 701 is implemented as a gain sliced (e.g., Cascode sliced) power amplifier, with multiple amplifiers of the output Tx power amplifier switchable by Cascode gain control 720. For such a device, the detection signals 408 and thermistor 402 sample can be used by control circuitry 710 of the device 700 to generate a gain measurement and to access a temperature compensated gain value. The control feedback for VSWR-tolerance in the device 700, however, involves an adjustment to the Cascode gain control 720. In some aspects, a counter can be incremented or decremented, as described above, with the Cascode gain control 720 matching the counter value. In such an implementation, the bits of the counter are used to turn power amplifier gain bits of the Cascode gain control 720 on and off to adjust the gain of the output Tx power amplifier according to the identified mismatch. In other aspects, other such controls can be used as feedback to modify output Tx power amplifier operation in response to a measured an expected gain value difference (e.g., a mismatch associated with VSWR and antenna impedance variation).

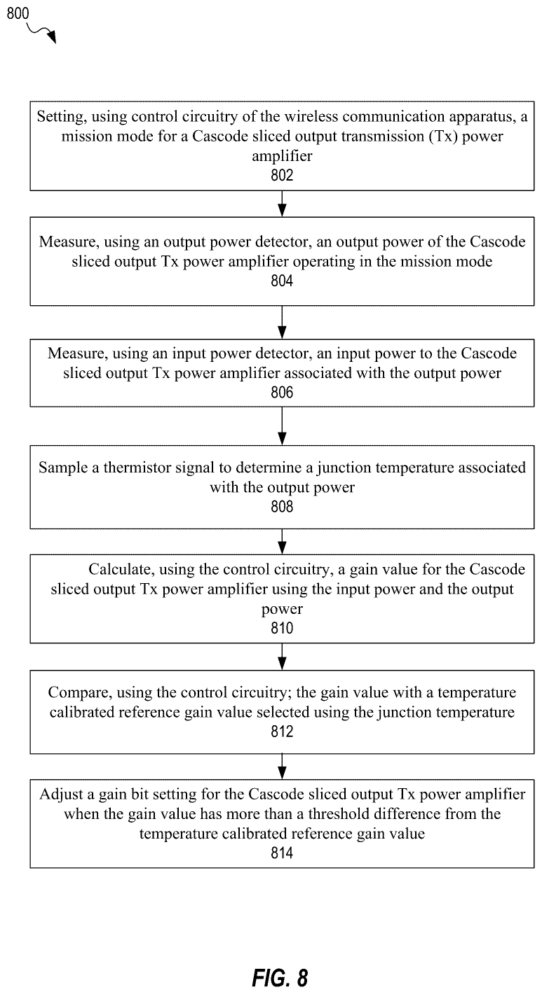

FIG. 8 is a flow diagram describing a method for operation of a device in accordance with aspects described herein. The blocks in the method 800 can be performed in or out of the order shown, and in some embodiments, can be performed at least in part in parallel.

Method 800 includes block 802, which describes setting, setting, using control circuitry of the wireless communication apparatus, a mission mode for a Cascode sliced output transmission (Tx) power amplifier. The method 800 further includes block 804, which describes measuring, using an output power detector, an output power of the Cascode sliced output Tx power amplifier operating in the mission mode. The method 800 further includes block 806, which describes measuring, using an input power detector, an input power to the Cascode sliced output Tx power amplifier associated with the output power. The method 800 further includes block 808, which describes sampling a thermistor signal to determine a junction temperature associated with the output power. The method 800 further includes block 810, which describes calculating, using the control circuitry, a gain value for the Cascode sliced output Tx power amplifier using the input power and the output power. The method 800 further includes block 812, which describes comparing, using the control circuitry; the gain value with a temperature calibrated reference gain value selected using the junction temperature. The method 800 further includes block 814, which describes adjusting a gain bit setting for the Cascode sliced output Tx power amplifier when the gain value has more than a threshold difference from the temperature calibrated reference gain value.

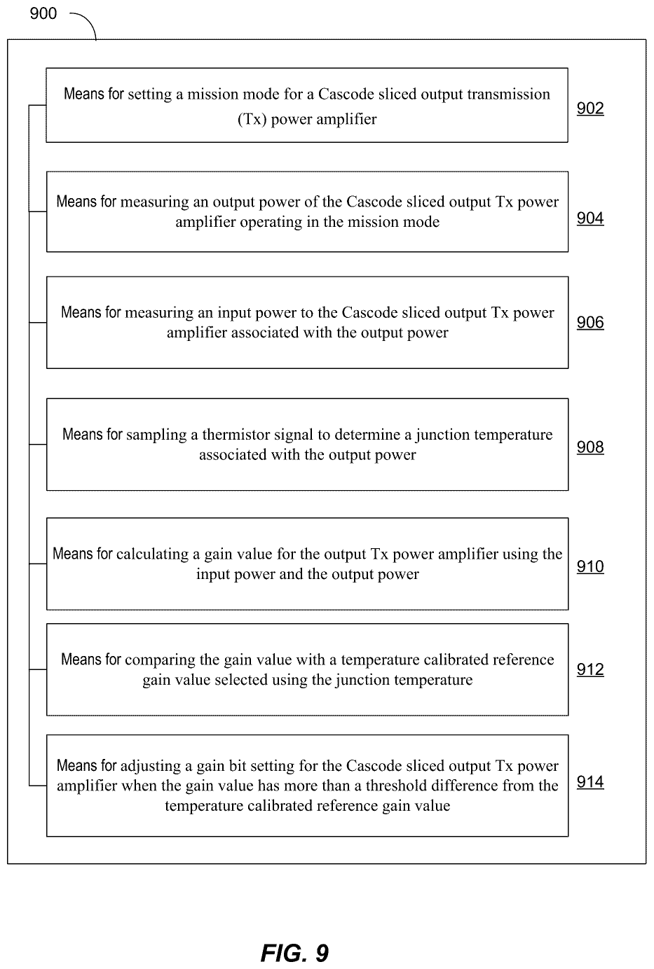

FIG. 9 is a functional block diagram of an apparatus including a power amplifier configured for VSWR-tolerant operation in accordance with some aspects. The apparatus 900 comprises means 902 for setting a mission mode for a Cascode sliced output transmission (Tx) power amplifier, means 904 for measuring an output power of the Cascode sliced output Tx power amplifier operating in the mission mode means 906 for measuring an input power to the Cascode sliced output Tx power amplifier associated with the output power, means 908 for sampling a thermistor signal to determine a junction temperature associated with the output power, means 910 for calculating, using the control circuitry, a gain value for the Cascode sliced output Tx power amplifier using the input power and the output power, means 912 for comparing, using the control circuitry; the gain value with a temperature calibrated reference gain value selected using the junction temperature, and means 914 for adjusting a gain bit setting for the Cascode sliced output Tx power amplifier when the gain value has more than a threshold difference from the temperature calibrated reference gain value.

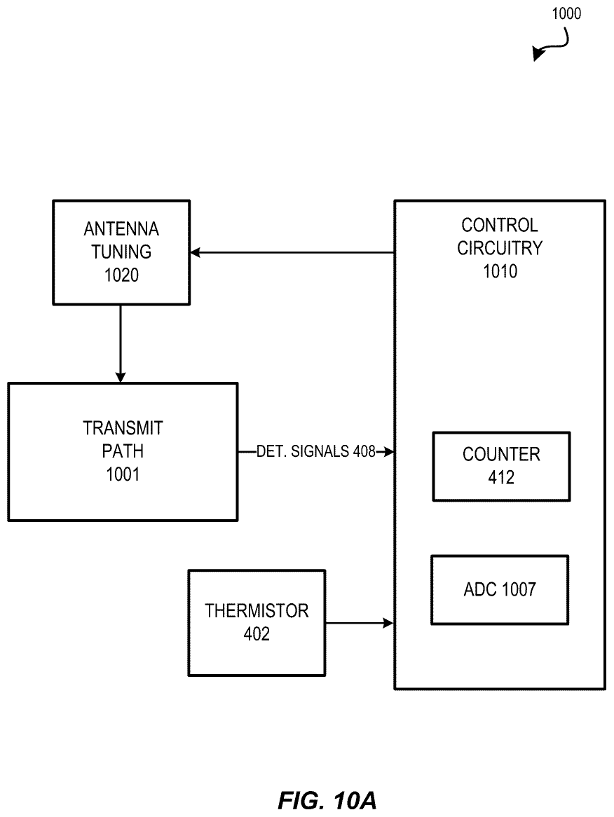

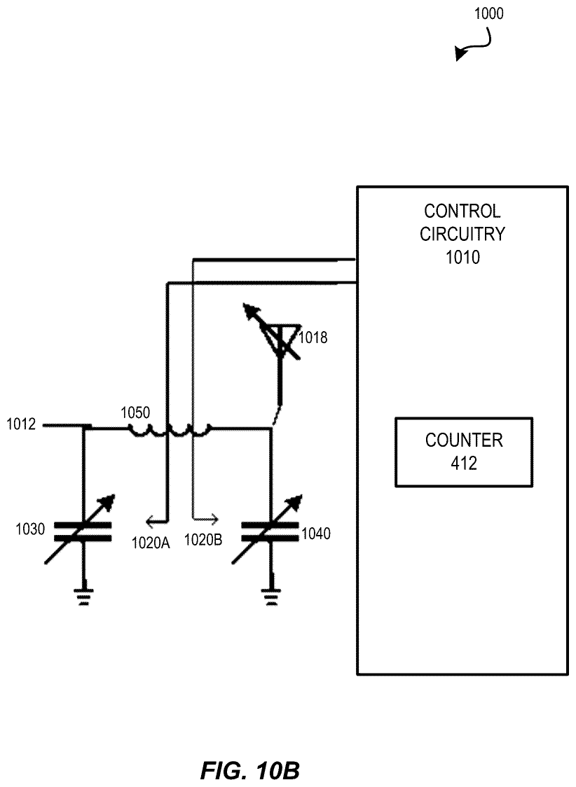

FIG. 10A is a diagram illustrating aspects of a device 1000 including a power amplifier configured for VSWR-tolerant operation in accordance with aspects described herein. The device 10A includes control circuitry 1010 similar to the control circuitry 410, and has a feedback signal to at least one transmit path 1001. Just as for other devices configured in accordance with aspects herein, additional transmit paths can include the circuitry described below configured with similar control operations.

Additionally, just as described above, the detection signals 408 from the transmit path 1001 are received by the control circuitry 1010 and used to determine a gain at a particular time for an output Tx power amplifier of the transmit path. The thermistor 402 generates a signal that is sampled by the control circuitry 1010 (e.g., an ADC 1007 similar to the ADC 307 or other such control circuitry) to identify a temperature calibrated reference gain value associated with the temperature determined from the thermistor 402 sample.

In FIG. 10A, however, the feedback signal from the control circuitry 1010 used to compensate for VSWR changes is an antenna tuning signal 1020. Such an antenna tuning signal can be used to adjust a tuning circuit included in a transmit path 1001.

FIG. 10B is a diagram illustrating aspects of the device 1000 including an antenna tuning circuit of a signal path for use with a power amplifier configured for VSWR-tolerant operation in accordance with aspects described herein. As illustrated in FIG. 10B, the control circuitry 1010 is coupled to tunable capacitors to provide the antenna tuning signal 1020, in the form of tuning signal 1020A for a tunable capacitor 1030, and tuning signal 1020B for a tunable capacitor 1040. The capacitors 1030 and 1040 are part of an implementation of the signal path 1001 positioned at the connection 1012 between a power amplifier and the antenna 1018 (e.g., similar to the connection 312 between the power amplifier 310 and the antenna 318). The tuning circuitry of the signal path includes tunable capacitors 1030, 1040 and inductor 1050 which can be used to compensate for VSWR changes as discussed above.

In the implementation of FIG. 10B, the gain and reference gain values can be determined as discussed above using the detector signals 408 and the thermistor 402 samples. If the measured gain from the detector signals 408 is higher than the reference value determined from the thermistor 402 samples, the capacitance of the tunable capacitor 1030 can be incremented, and the capacitance of the tunable capacitor 1040 can be decremented. If the measured gain from the detector signals 408 is lower than the reference value determined from the thermistor 402 samples, the capacitance of the tunable capacitor 1030 can be decremented, and the capacitance of the tunable capacitor 1040 can be incremented. In some aspects, the counter 412 can be used to implement such adjustments to the antenna tuning signals 1020A, 1020B. In other aspects, other controls can be used for antenna tuning signals 1020.

In some aspects, the antenna tuning of FIGS. 10A and 10B can be combined with other operations described above in the Cascode tuning for the device of FIG. 7 or the bias tuning for the device of FIG. 4. For example, both antenna tuning as described above and bias tuning can be performed in a single device having the supporting circuitry described separately above, but included in a single device, with additional loop operations for each tuning operation performed by control circuitry (e.g., the control circuitry 1010.)

Additionally, as described in FIGS. 4, 7, and 10A/10B, the above described VSWR tuning can be performed for a device or wireless communication with a single transmit path (e.g., the transmit path 301 of FIG. 3 with no other transmit paths). In other aspects, a VSWR tuning described above can be performed for any number of transmit paths in a device with an array of elements driven by transmit paths with the illustrated circuitry. For such arrays, the operations described above can be performed separately for each signal path to independently tune each signal path. Such operations can be performed serially by corresponding control circuitry as part of a device operating mode loop or mission mode loop. The operations can be paused to conserve power when the device is configured for a non-operating or a non-mission mode (e.g., any modes where excessive power or wear on output Tx power amplifiers is unlikely or not possible).

For a multi-element transmitter (e.g., a Tx output path with multiple power amplifiers or other adjustable transmitter elements in the Tx output path), the above technique can be used without comparing the gain for each transmitter to a reference calibrated gain. Instead, a reference calibrated gain can be created for a mean gain of all the transmitter elements. During operation, the gain of each element can be measured, and control circuitry can be used to calculate a mean operating gain of the transmitter elements in the Tx path. The mean operating gain of the Tx path can then be compared with the reference calibrated gain, and the difference between the mean operating gain and the reference calibrated gain can be used to adjust individual transmitter elements accordingly (e.g., using voltage adjustments or gain slicing adjustments on individual transmitter elements to bring the mean operating gain to within a threshold distance of the reference calibrated gain for the Tx path in the multi-transmitter element system). In such a multi-element transmitter, any number of the transmitter elements may be adjustable, and control circuitry may select which element to adjust based on secondary factors, such as the operating gain of an individual element against individual device performance, or other such secondary factors.

In some aspects of a multi-element system, rather than using a reference calibrated gain, individual VSWR measurements are performed for each element of the multi-element system. A highest VSWR measurement is compared against a threshold value, and adjustments are made based on the highest VSWR measurement. In some such aspects, individual elements are adjusted separately. In other aspects, adjustments are made to all elements based on the highest VSWR measurement. In still other aspects, the reference calibrated gain systems of any aspect above can be combined with the compensation adjustments described for a multi-element system.

In some aspects, the mission mode loops including the operations above as part of a VSWR compensation loop are performed repeatedly as part of mission mode operation. Such loops can involve repeatedly updating gain values using updated power measurements and updated temperature determinations from updated thermistor samples. The feedback adjustment will be changed for each of the updating operations of the VSWR compensation loop, resulting in tracking VSWR changes over time.

In other aspects, triggers within mission mode operation can initiate the operations described above for each signal path. For example, for a phased array system, a beam switch or beam steering operation can trigger the VSWR tuning operations described above. In other aspects, other logic can be used to initiate VSWR tuning operations for VSWR-tolerant operations of a wireless communication apparatus.

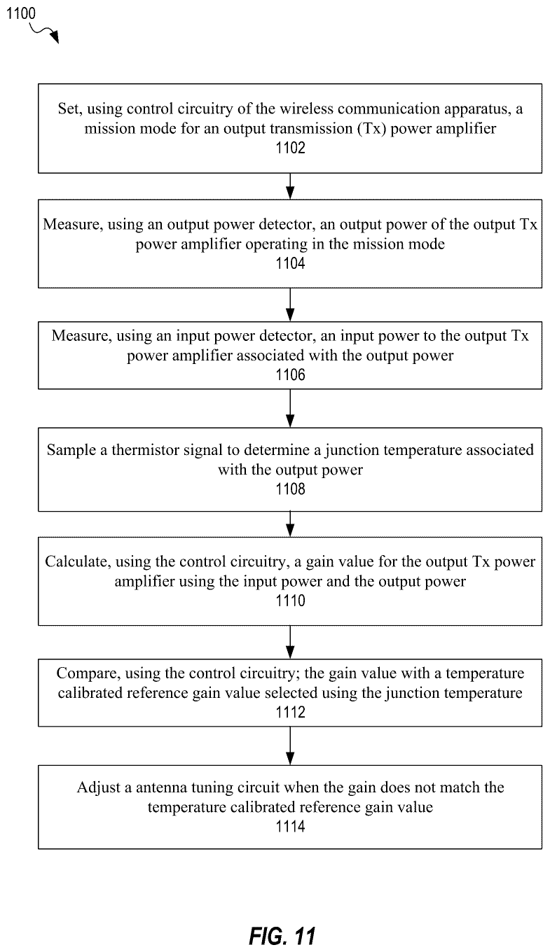

FIG. 11 is a flow diagram describing a method for operation of a device in accordance with aspects described herein. The blocks in the method 1100 can be performed in or out of the order shown, and in some embodiments, can be performed at least in part in parallel.

Method 1100 includes block 1102, which involves setting, using control circuitry of a wireless communication apparatus, a mission mode for an output transmission (Tx) power amplifier. The method 1100 further includes block 1104, which describes measuring, using an output power detector, an output power of the output Tx power amplifier operating in the mission mode. The method 1100 further includes block 1106, which describes measuring, using an input power detector, an input power to the output Tx power amplifier associated with the output power. The method 1100 further includes block 1108, which describes sampling a thermistor signal to determine a junction temperature associated with the output power. The method 1110 further includes block 1104, which describes calculating, using the control circuitry, a gain value for the output Tx power amplifier using the input power and the output power. The method 1100 further includes block 1112, which describes comparing, using the control circuitry; the gain value with a temperature calibrated reference gain value selected using the junction temperature. The method 1100 further includes block 1114, which describes adjusting an antenna tuning circuit when the gain value does not match the temperature calibrated reference gain value.

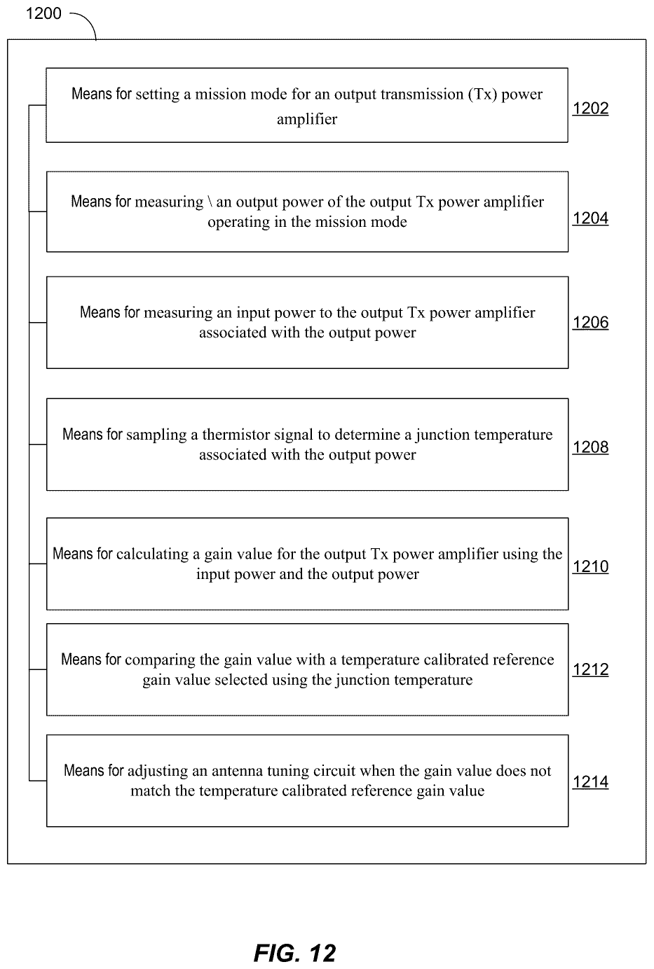

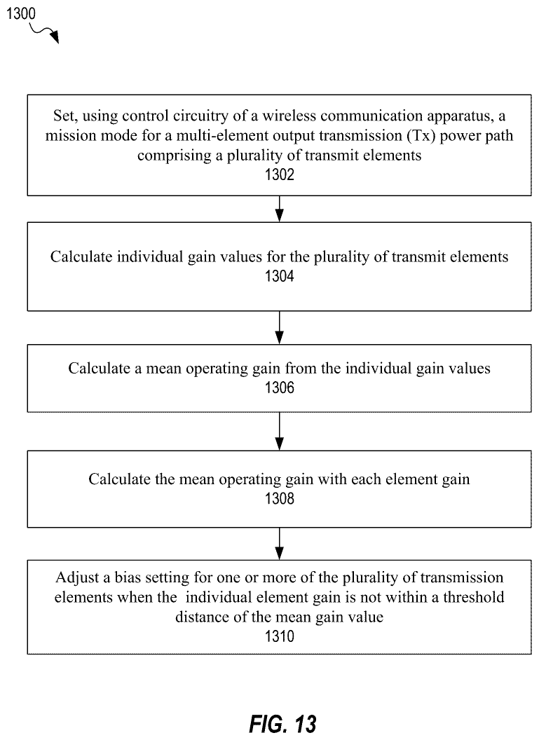

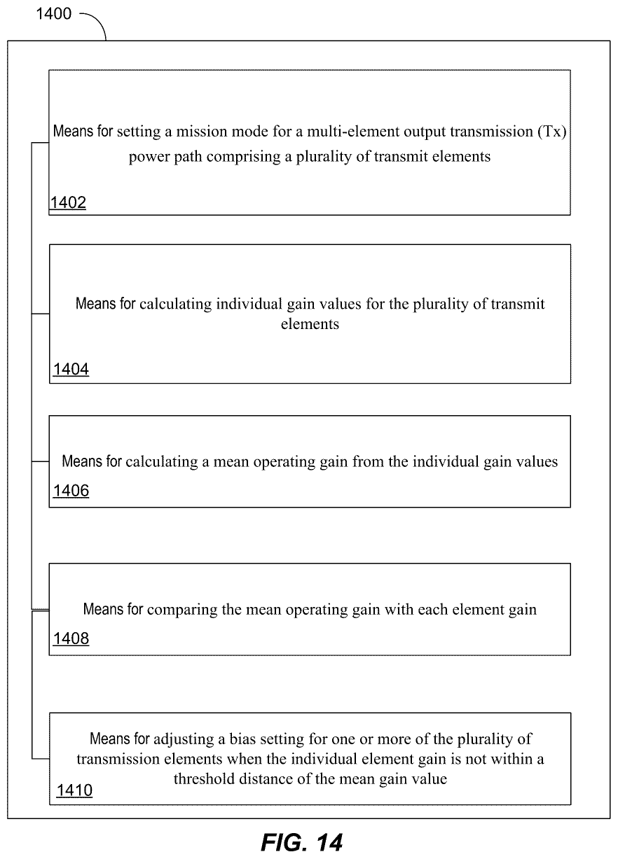

FIG. 12 is a functional block diagram of an apparatus including a power amplifier configured for VSWR-tolerant operation in accordance with some aspects. The apparatus 1200 comprises means 1202 for setting (e.g., using control circuitry 710) a mission mode for an output transmission (Tx) power amplifier, means 1204 for measuring, (e.g., using an output power detector such as the PDET 316), an output power of the output Tx power amplifier operating in the mission mode, means 1206 for measuring, (e.g., using an input power detector such as RDET 306), an input power to the output Tx power amplifier associated with the output power, means 1208 for sampling a thermistor signal to determine a junction temperature associated with the output power, means 1210 for calculating, using the control circuitry, a gain value for the output Tx power amplifier using the input power and the output power, means 1212 for comparing, using the control circuitry; the gain value with a temperature calibrated reference gain value selected using the junction temperature, and means 1214 for adjusting an antenna tuning circuit when the gain value does not match the temperature calibrated reference gain value.

FIG. 13 is a flow diagram describing a method for operation of a device in accordance with aspects described herein. The blocks in the method 1300 can be performed in or out of the order shown, and in some embodiments, can be performed at least in part in parallel.

Method 1300 includes block 1302, which describes setting, using control circuitry of a wireless communication apparatus, a mission mode for a multi-element output transmission (Tx) power path comprising a plurality of transmit elements. The method 1300 further includes block 1304, which describes calculating individual gain values for the plurality of transmit elements. The method 1300 further includes block 1306, which describes calculating a mean operating gain from the individual gain values. The method 1300 further includes block 1308, which describes comparing the mean operating gain with each element gain. The method 1300 further includes block 1310, which describes adjusting a bias setting for one or more of the plurality of transmission elements when the individual element gain is not within a threshold distance of the mean gain value.

In some aspects, the method 1300 can further involve operations for estimating corresponding voltage standing wave ratio (VSWR) values for transmit elements the multi-element output Tx power path, determining a highest VSWR value of the corresponding VSWR values, and performing, using control circuitry, an output Tx power amplifier protection action based on the highest VSWR value of the corresponding VSWR values. Similarly, some aspects of the method 1300 can further include determining a lowest VSWR value of the corresponding VSWR values, wherein the output Tx power amplifier protection action comprises adjusting a gate bias value for a power amplifier of the plurality of transmit elements when the lowest VSWR value is less than a threshold value. Some such aspects can operate where the output Tx power amplifier protection action comprises adjusting an input power to the multi-element output Tx power path when the highest VSWR value is greater than a threshold value. Some such aspects can operate where the output Tx power amplifier protection action comprises adjusting an antenna tuning circuit coupled to the output of the multi-element output Tx power path when a difference between the mean operating gain and a target reference gain value is greater than a predefined threshold value.

Any method described herein, including the method 1300, can operate with intervening or repeated steps. Additionally, other methods or combinations of the operations described above will be apparent within the context of the various aspects described herein.

FIG. 14 is a functional block diagram of an apparatus including a power amplifier configured for VSWR-tolerant operation in accordance with some aspects. The apparatus 1400 comprises means 1402 for setting a mission mode for a multi-element output transmission (Tx) power path comprising a plurality of transmit elements, means 1404 for calculating individual gain values for the plurality of transmit elements, means 1406 for calculating a mean operating gain from the individual gain values, means 1408 for comparing the mean operating gain with each element gain, and means 1410 for adjusting a bias setting for one or more of the plurality of transmission elements when the individual element gain is not within a threshold distance of the mean gain value.

Devices, networks, systems, and certain means for transmitting or receiving signals described herein may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHz-7.125 GHz) and FR2 (24.25 GHz-52.6 GHz). The frequencies between FR1 and FR2 are often referred to as mid-band frequencies. Although a portion of FR1 is greater than 6 GHz, FR1 is often referred to (interchangeably) as a “sub-6 GHz” band in various documents and articles, and will be referred to herein as “sub-7 GHz”. A similar nomenclature issue sometimes occurs with regard to FR2, which is often referred to (interchangeably) as a “millimeter wave” (mmW) band in documents and articles, despite including frequencies outside of the extremely high frequency (EHF) band (30 GHz-300 GHz) which is identified by the International Telecommunications Union (ITU) as a “mmWave” or mmW band. Unless specifically stated otherwise, it should be understood that the term “mmWave”, mmW, or the like if used herein may broadly represent frequencies that may include mid-band frequencies, may be within FR2, or may be within the EHF band.

The circuit architecture described herein may be implemented on one or more ICs, analog ICs, mmWICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR) or corresponding mmW elements, (iv) an ASIC such as a mobile station modem (MSM), (v) a module that may be embedded within other devices, (vi) a receiver, cellular phone, wireless device, handset, or mobile unit, (vii) etc.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

Although selected aspects have been illustrated and described in detail, it will be understood that various substitutions and alterations may be made therein without departing from the spirit and scope of the present invention, as defined by the following claims.

Illustrative aspects of the present disclosure include, but are not limited to:
Aspect 1: A method of operating a wireless communication apparatus, comprising: setting, using control circuitry of the wireless communication apparatus, a mission mode for an output transmission (Tx) power amplifier; measuring, using an output power detector, an output power of the output Tx power amplifier operating in the mission mode; measuring, using an input power detector, an input power to the output Tx power amplifier associated with the output power; sampling a thermistor signal to determine a junction temperature associated with the output power; calculating, using the control circuitry, a gain value for the output Tx power amplifier using the input power and the output power; comparing, using the control circuitry; the gain value with a temperature calibrated reference gain value selected using the junction temperature; and adjusting a power amplifier bias when the gain value is different from the temperature calibrated reference gain value.
Aspect 2. The method of Aspect 1, wherein adjusting the power amplifier bias comprises: incrementing a counter that used to generate the power amplifier bias when the gain value is above the temperature calibrated reference gain value; and decrementing the counter when the gain value is below the temperature calibrated reference gain value.
Aspect 3. The method of Aspect 2, further comprising: updating the gain value with an updated output power measurement, an updated input power measurement, and an updated thermistor sample approximately every millisecond (ms); and updating the power amplifier bias as part of a voltage standing wave ratio (VSWR) compensation loop.
Aspect 4. The method of any of Aspects 1 to 3, further comprising estimating a voltage standing wave ratio (VSWR) value using the input power and the output power without using a peak detector measurement for the signaling of the power back-off.
Aspect 5. The method of any of Aspects 1 to 4, further comprising: estimating a voltage standing wave ratio (VSWR) value using the input power and the output power; and performing, using the control circuitry, an output Tx power amplifier protection action based on the VSWR value.
Aspect 6. The method Aspect 5, wherein the output Tx power amplifier protection action comprises adjusting a gate bias value for the output Tx power amplifier when the VSWR value is less than 2:1.
Aspect 7. The method Aspect 5, wherein the output Tx power amplifier protection action comprises adjusting an input power to the output Tx power amplifier when the VSWR value is greater than 2:1.
Aspect 8. The method Aspect 5, wherein the output Tx power amplifier protection action comprises adjusting an automatic gain control setting of the output Tx power amplifier when the VSWR value is greater than 2:1.
Aspect 9. The method of any of Aspects 1 to 8, further comprising: comparing, using the control circuitry, the gain value with a low impedance estimate threshold value; and lowering a supply voltage for the output Tx power amplifier and increasing the power amplifier bias to improve a linear power efficiency when the gain value is below the low impedance estimate threshold value.
Aspect 10. The method of any of Aspects 1 to 9, further comprising: comparing, using the control circuitry, the gain value with a high impedance estimate threshold value; and setting a supply voltage for the output Tx power amplifier to a maximum value and lowering an input power to the output Tx power amplifier.
Aspect 11. A method of operating a wireless communication apparatus, comprising: setting, using control circuitry of the wireless communication apparatus, a mission mode for a Cascode sliced output transmission (Tx) power amplifier; measuring, using an output power detector, an output power of the Cascode sliced output Tx power amplifier operating in the mission mode; measuring, using an input power detector, an input power to the Cascode sliced output Tx power amplifier associated with the output power; sampling a thermistor signal to determine a junction temperature associated with the output power; calculating, using the control circuitry, a gain value for the Cascode sliced output Tx power amplifier using the input power and the output power; comparing, using the control circuitry; the gain value with a temperature calibrated reference gain value selected using the junction temperature; and adjusting a gain bit setting for the Cascode sliced output Tx power amplifier when the gain value has more than a threshold difference from the temperature calibrated reference gain value.
Aspect 12. The method of Aspect 11, further comprising: estimating a voltage standing wave ratio (VSWR) value using the input power and the output power; and performing, using the control circuitry, an output Tx power amplifier protection action based on the VSWR value.
Aspect 13. The method of Aspect 12, wherein the output Tx power amplifier protection action comprises adjusting a gate bias value for the output Tx power amplifier when the VSWR value is less than a threshold value.
Aspect 14. The method of Aspect 12, wherein the output Tx power amplifier protection action comprises adjusting the gain bit setting to lower the gain value when the VSWR value is greater than a threshold value.
Aspect 15. The method of Aspect 12, wherein the output Tx power amplifier protection action comprises signaling a power back-off of the output Tx power amplifier based on the VSWR value exceeding a threshold value, without using a peak detector measurement for the signaling of the power back-off.
Aspect 16. A method, comprising: setting, using control circuitry of a wireless communication apparatus, a mission mode for a multi-element output transmission (Tx) power path comprising a plurality of transmit elements; calculating individual gain values for the plurality of transmit elements; calculating a mean operating gain from the individual gain values; comparing the mean operating gain with the individual gain values; and adjusting a bias setting for one or more of the plurality of transmit elements when a first gain value of the individual gain values is not within a threshold distance of the mean operating gain.
Aspect 17. The method of Aspect 16, further comprising: estimating corresponding voltage standing wave ratio (VSWR) values for transmit elements the multi-element output Tx power path; determining a highest VSWR value of the corresponding VSWR values; performing, using control circuitry, an output Tx power amplifier protection action based on the highest VSWR value of the corresponding VSWR values.
Aspect 18. The method of Aspect 17, further comprising determining a lowest VSWR value of the corresponding VSWR values, wherein the output Tx power amplifier protection action comprises adjusting a gate bias value for a power amplifier of the plurality of transmit elements when the lowest VSWR value is less than a threshold value.
Aspect 19. The method of Aspect 17, wherein the output Tx power amplifier protection action comprises adjusting an input power to the multi-element output Tx power path when the highest VSWR value is greater than a threshold value.
Aspect 20. The method of Aspect 17, wherein the output Tx power amplifier protection action comprises adjusting an antenna tuning circuit coupled to the output of the multi-element output Tx power path when a difference between the mean operating gain and a target reference gain value is greater than a predefined threshold value.
Aspect 21. A method, comprising: setting, using control circuitry of a wireless communication apparatus, a mission mode for an output transmission (Tx) power amplifier; measuring, using an output power detector, an output power of the output Tx power amplifier operating in the mission mode; measuring, using an input power detector, an input power to the output Tx power amplifier associated with the output power; sampling a thermistor signal to determine a junction temperature associated with the output power; calculating, using the control circuitry, a gain value for the output Tx power amplifier using the input power and the output power; comparing, using the control circuitry; the gain value with a temperature calibrated reference gain value selected using the junction temperature; and adjusting an antenna tuning circuit when the gain value does not match the temperature calibrated reference gain value.
Aspect 22. A device configured to operate in accordance with any method above.
Aspect 23. A device comprising means for performing the operations of any method above.

What is claimed is:

1. A method of operating a wireless communication apparatus, comprising:
setting, using control circuitry of the wireless communication apparatus, a mission mode for an output transmission (Tx) power amplifier;
measuring, using an output power detector, an output power of the output Tx power amplifier operating in the mission mode;
measuring, using an input power detector, an input power to the output Tx power amplifier associated with the output power;
sampling a thermistor signal to determine a junction temperature associated with the output power;
calculating, using the control circuitry, a gain value for the output Tx power amplifier using the input power and the output power;
comparing, using the control circuitry; the gain value with a temperature calibrated reference gain value selected using the junction temperature; and
adjusting a power amplifier bias when the gain value is different from the temperature calibrated reference gain value.

2. The method of claim 1, wherein adjusting the power amplifier bias comprises:
incrementing a counter that used to generate the power amplifier bias when the gain value is above the temperature calibrated reference gain value; and
decrementing the counter when the gain value is below the temperature calibrated reference gain value.

3. The method of claim 2, further comprising:
updating the gain value with an updated output power measurement, an updated input power measurement, and an updated thermistor sample approximately every millisecond (ms); and
updating the power amplifier bias as part of a voltage standing wave ratio (VSWR) compensation loop.

4. The method of claim 1, further comprising estimating a voltage standing wave ratio (VSWR) value using the input power and the output power; and
signaling a power back-off of the output Tx power amplifier based on the VSWR value exceeding a threshold value, without using a peak detector measurement for the signaling of the power back-off.

5. The method of claim 1, further comprising:
estimating a voltage standing wave ratio (VSWR) value using the input power and the output power; and
performing, using the control circuitry, an output Tx power amplifier protection action based on the VSWR value.

6. The method of claim 5, wherein the output Tx power amplifier protection action comprises adjusting a gate bias value for the output Tx power amplifier when the VSWR value is less than 2:1.

7. The method of claim 5, wherein the output Tx power amplifier protection action comprises adjusting an input power to the output Tx power amplifier when the VSWR value is greater than 2:1.

8. The method of claim 5, wherein the output Tx power amplifier protection action comprises adjusting an automatic gain control setting of the output Tx power amplifier when the VSWR value is greater than 2:1.

9. The method of claim 1, further comprising:
comparing, using the control circuitry, the gain value with a low impedance estimate threshold value; and
lowering a supply voltage for the output Tx power amplifier and increasing the power amplifier bias to improve a linear power efficiency when the gain value is below the low impedance estimate threshold value.

10. The method of claim 1, further comprising:
comparing, using the control circuitry, the gain value with a high impedance estimate threshold value; and
setting a supply voltage for the output Tx power amplifier to a maximum value and lowering an input power to the output Tx power amplifier.

11. A method of operating a wireless communication apparatus, comprising:
setting, using control circuitry of the wireless communication apparatus, a mission mode for a Cascode sliced output transmission (Tx) power amplifier;
measuring, using an output power detector, an output power of the Cascode sliced output Tx power amplifier operating in the mission mode;
measuring, using an input power detector, an input power to the Cascode sliced output Tx power amplifier associated with the output power;
sampling a thermistor signal to determine a junction temperature associated with the output power;
calculating, using the control circuitry, a gain value for the Cascode sliced output Tx power amplifier using the input power and the output power;
comparing, using the control circuitry; the gain value with a temperature calibrated reference gain value selected using the junction temperature; and
adjusting a gain bit setting for the Cascode sliced output Tx power amplifier when the gain value has more than a threshold difference from the temperature calibrated reference gain value.

12. The method of claim 11, further comprising:
estimating a voltage standing wave ratio (VSWR) value using the input power and the output power; and
performing, using the control circuitry, an output Tx power amplifier protection action based on the VSWR value.

13. The method of claim 12, wherein the output Tx power amplifier protection action comprises adjusting a gate bias value for the output Tx power amplifier when the VSWR value is less than a threshold value.

14. The method of claim 12, wherein the output Tx power amplifier protection action comprises adjusting the gain bit setting to lower the gain value when the VSWR value is greater than a threshold value.

15. The method of claim 12, wherein the output Tx power amplifier protection action comprises signaling a power back-off of the output Tx power amplifier based on the VSWR value exceeding a threshold value, without using a peak detector measurement for the signaling of the power back-off.

16. A method, comprising:
setting, using control circuitry of a wireless communication apparatus, a mission mode for a multi-element output transmission (Tx) power path comprising a plurality of transmit elements;
calculating individual gain values for the plurality of transmit elements;
calculating a mean operating gain from the individual gain values;
comparing the mean operating gain with the individual gain values; and
adjusting a bias setting for one or more of the plurality of transmit elements when a first gain value of the individual gain values is not within a threshold distance of the mean operating gain.

17. The method of claim 16, further comprising:
estimating corresponding voltage standing wave ratio (VSWR) values for transmit elements the multi-element output Tx power path;
determining a highest VSWR value of the corresponding VSWR values;
performing, using control circuitry, an output Tx power amplifier protection action based on the highest VSWR value of the corresponding VSWR values.

18. The method of claim 17, further comprising determining a lowest VSWR value of the corresponding VSWR values, wherein the output Tx power amplifier protection action comprises adjusting a gate bias value for a power amplifier of the plurality of transmit elements when the lowest VSWR value is less than a threshold value.

19. The method of claim 17, wherein the output Tx power amplifier protection action comprises adjusting an input power to the multi-element output Tx power path when the highest VSWR value is greater than a threshold value.

20. The method of claim 17, wherein the output Tx power amplifier protection action comprises adjusting an antenna tuning circuit coupled to an output of the multi-element output Tx power path when a difference between the mean operating gain and a target reference gain value is greater than a predefined threshold value.
